(19) United States
(12) Patent Application Publication
(10) Pub. No.: US 2025/0359106 A1
(43) Pub. Date: Nov. 20, 2025

(54) MANUFACTURING METHOD OF SEMICONDUCTOR LAYER AND TRANSISTOR COMPRISING THE SEMICONDUCTOR LAYER

(71) Applicant: SAMSUNG DISPLAY CO., LTD., YONGIN-SI (KR)

(72) Inventor: Hyung Jun KIM, Yongin-si (KR)

(21) Appl. No.: 18/982,365

(22) Filed: Dec. 16, 2024

(30) Foreign Application Priority Data
May 14, 2024 (KR) 10-2024-0063008

(51) Int. Cl. H10D 30/01; H01L 21/02; H01L 21/033; H10D 30/47; H10D 30/67; H10D 62/80

(52) U.S. Cl. CPC H10D 30/017; H01L 21/02568; H01L 21/02658; H10D 30/031; H10D 30/481; H10D 30/674; H01L 21/0242; H01L 21/0332; H10D 62/883

(57) ABSTRACT

A method of manufacturing a semiconductor layer includes preparing an insulating layer comprising a silicon oxide. A metal mask is formed on the insulating layer. An oxygen plasma process is performed on the metal mask. The metal mask is removed. The insulating layer is loaded into a chamber to form a semiconductor layer.

### CROSS-REFERENCE TO RELATED APPLICATION

This application claims priority under 35 U.S.C. § 119 to Korean Patent Application No. 10-2024-0063008, filed on May 14, 2024 in the Korean Intellectual Property Office, the disclosure of which is incorporated by reference in its entirety herein.

### 1. TECHNICAL FIELD

The present disclosure relates to a method of manufacturing a semiconductor layer and a transistor including the semiconductor layer manufactured therefrom.

### 2. DISCUSSION OF RELATED ART

Semiconductor materials with a layered structure are attracting attention as next-generation semiconductor materials due to their flexibility and transparency.

Transition metal dichalcogenides (TMDCs) are gaining attention as materials for next-generation electronic devices having characteristics such as thin film thickness, high mobility (tens to hundreds of cm2/V-s), and high on/off ratio. For example, research is being conducted with respect to TMDCs as channel materials for transparent and flexible display thin film transistors, channel materials to overcome the scaling of electronic devices, and materials for electronic sensors with high sensitivity characteristics.

### SUMMARY

Embodiments of the present disclosure provide a method of manufacturing a semiconductor layer that is easy to manufacture and has increased reliability, and a transistor including the semiconductor layer manufactured therefrom.

According to an embodiment of the present disclosure, a method of manufacturing a semiconductor layer includes preparing an insulating layer comprising a silicon oxide. A metal mask is formed on the insulating layer. An oxygen plasma process is performed on the metal mask. The metal mask is removed. The insulating layer is loaded into a chamber to form a semiconductor layer.

In an embodiment, a thickness of the insulating layer may be in a range of about 200 nanometers to about 400 nanometers.

In an embodiment, through the oxygen plasma process, the insulating layer may include a first region and a second region having different surface energies from each other.

In an embodiment, the first region may have a higher surface energy than the second region.

In an embodiment, the first region may have hydrophilicity, and the second region may have hydrophobicity.

In an embodiment, the first region may include a Si—O—H bond, and the second region may include a Si—O—Si bond.

In an embodiment, the metal mask may include at least one compound selected from molybdenum (Mo), gold (Au), silver (Ag), copper (Cu), and titanium (Ti).

In an embodiment, the metal mask may have a thickness in a range of about 50 nanometers to about 150 nanometers.

In an embodiment, the metal mask may be formed through a patterning process after forming a metal layer on the insulating layer.

In an embodiment, the oxygen plasma process may be performed at a power in a range of about 150 W to about 250 W.

In an embodiment, the oxygen plasma process may be performed for a time period in a range of about 200 seconds to about 400 seconds.

In an embodiment, the method may further include a step of injecting a precursor, a reactant, and an inert gas into the chamber to form the semiconductor layer.

In an embodiment, the precursor may be injected in an amount in a range of about 0.3 mg to about 0.7 mg, and the reactant may be injected in an amount in a range of about 330 mg to about 370 mg.

In an embodiment, the reactant may be injected in an amount in a range of about 500 to about 1000 times that of the precursor.

In an embodiment, the precursor and the reactant may react to form a semiconductor layer having a layered structure on the first region.

In an embodiment, the semiconductor layer having the layered structure may includes a compound represented by a chemical formula XYa in which X is one of Mo, W, Zr, and Re, Y is one of S, Se, and Te, and a may be a natural number greater than or equal to 1.

In an embodiment, the semiconductor layer having the layered structure may include at least one compound selected from MoS₂, MoSe₂, WS₂, WSe₂, MoTe₂, WTe₂, ZrS₂, ZrSe₂, ZrTe₂, ReS₂, ReSe₂, and ReTe₂.

According to an embodiment, the transistor includes a substrate. A semiconductor layer is disposed on the substrate. A gate electrode overlaps a portion of the semiconductor layer. Source and drain electrodes are electrically connected to the semiconductor layer. The semiconductor layer is manufactured through the method of manufacturing the semiconductor layer.

According to an embodiment of the present disclosure, a method of manufacturing a semiconductor layer includes preparing a substrate comprising silicon. An insulating layer comprising silicon oxide is formed on the substrate. A metal layer is formed on the insulating layer. The metal layer is patterned to form a metal mask having an opening area. An oxygen plasma process is performed on the metal mask. The oxygen plasma process forms a first region of the insulating layer that is exposed by the opening area of the metal mask during the performing of the oxygen plasma process and a second region of the insulating layer that is covered by the metal mask during the performing of the oxygen plasma process. The semiconductor layer is formed on the first region. The first region has hydrophilicity and the second region has hydrophobicity.

In an embodiment, the first region has a higher surface energy than the second region.

In an embodiment, the semiconductor layer is formed on the first region through a chemical vapor deposition process, a plasma chemical vapor deposition process, an atomic layer deposition process or a sputter process.

In an embodiment, the first region has a contact angle in a range of about 5 degrees or less. The second region has a contact angle in a range of about 30 degrees to about 60 degrees.

According to embodiments, a method of manufacturing a semiconductor layer that is easy to manufacture and has increased reliability, and a transistor including the semiconductor layer manufactured therefrom, may be provided.

### BRIEF DESCRIPTION OF THE DRAWINGS

FIG. 1 is a cross-sectional view showing a transistor according to an embodiment of the present disclosure.

FIGS. 2 to 10 are diagrams of some components according to a method of manufacturing a semiconductor layer according to embodiments of the present disclosure.

FIG. 11 (a) is an optical image of a semiconductor layer manufactured according to an example, and FIG. 11 (b) is a graph measuring the height of each pattern in FIG. 11 (a).

FIG. 12 is a SEM image of a semiconductor layer manufactured according to an embodiment of the present disclosure.

FIG. 13 is a Raman graph for a semiconductor layer manufactured according to an embodiment of the present disclosure.

FIG. 14 is a Raman mapping image of a semiconductor layer manufactured according to an embodiment of the present disclosure.

FIGS. 15 to 17 are atomic force microscopy AFM images of a plasma treated surface according to embodiments of the present disclosure.

FIG. 18 is a Lateral Force Microscopy LFM image of a plasma treated surface according to an embodiment of the present disclosure.

FIG. 19 is a graph showing the lateral force for each area according to an embodiment of the present disclosure.

### DETAILED DESCRIPTION OF EMBODIMENTS

Hereinafter, with reference to the attached drawings, various non-limiting embodiments of the present disclosure will be described in detail so that those skilled in the art may easily implement the present disclosure. However, the present disclosure may be implemented in many different forms and is not limited to embodiments described herein.

To clearly explain embodiments of the present disclosure, parts that are not relevant to the description may be omitted, and identical or similar components are assigned the same reference numerals throughout the specification.

In addition, the size and thickness of each component shown in the drawings may be arbitrarily shown for convenience of explanation, and embodiments of the present disclosure are not necessarily limited to that which is shown. In the drawings, the thicknesses may be enlarged to clearly express various layers and areas. And in the drawings, for convenience of explanation, the thicknesses of some layers and regions may be exaggerated.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part means being disposed above or below the reference part, and does not necessarily mean being disposed “above” or “on” it in the direction opposite to gravity.

In addition, throughout the specification, when a part, component or element is said to “include” a certain component, this means that it may further include other components rather than excluding other components, unless specifically stated to the contrary.

In addition, throughout the specification, when reference is made to “on a plane,” this means when the target part is viewed from above, and when reference is made to “in a cross-section,” this means when a cross-section of the target portion is cut vertically and viewed from the side.

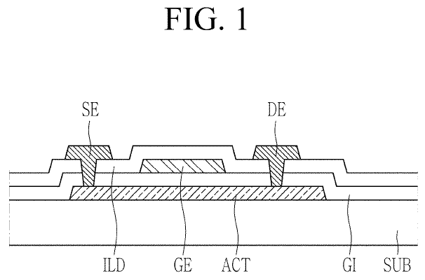

Hereinafter, a transistor according to an embodiment will be described with reference to FIG. 1. FIG. 1 is a cross-sectional view showing a transistor according to an embodiment.

Referring to FIG. 1, a transistor according to an embodiment may be disposed on a substrate SUB. In a embodiment, the substrate SUB may include transparent glass. However, embodiments of the present disclosure are not necessarily limited thereto and the substrate SUB may include various materials such as transparent plastic or metal.

In an embodiment, a buffer layer may also be disposed on (e.g., disposed directly thereon) the substrate SUB. The buffer layer may prevent impurity ions from diffusing into the semiconductor layer, prevent moisture or external air from penetrating, and flatten the surface. In an embodiment, the buffer layer may be composed of an inorganic material.

A semiconductor layer ACT may be disposed on the substrate SUB.

In an embodiment, the semiconductor layer ACT contains a two-dimensional semiconductor material. Two-dimensional semiconductor materials refer to semiconductor materials that have a layered structure in which constituent atoms are two-dimensionally bonded to each other. Two-dimensional semiconductor materials have excellent electrical properties and may maintain high mobility without significantly changing their properties even when the thickness is reduced to the nanoscale.

In an embodiment, two-dimensional semiconductor materials may include materials having a bandgap in a range of about 0.1 eV to about 3.0 eV. However, embodiments of the present disclosure are not necessarily limited thereto. In an embodiment, the two-dimensional semiconductor material may include, for example, a transition metal dichalcogenide TMDC, black phosphorus, or graphene.

The semiconductor layer ACT may include, for example, a semiconductor material having a layered structure. In an embodiment, the semiconductor material having the layered structure may be a transition metal chalcogenide TMDC.

In an embodiment, the semiconductor material having the layered structure may include a compound represented by the chemical formula XYa in which X is one of Mo, W, Zr, and Re, Y is one of S, Se, and Te, and a may be a natural number greater than or equal to 1. For example, in an embodiment the semiconductor material having the layered structure may include at least one of MoS₂, MoSe₂, WS₂, WSe₂, MoTe₂, WTe₂, ZrS₂, ZrSe₂, ZrTe₂, ReS₂, ReSe₂, and ReTe₂.

The two-dimensional semiconductor material constituting the semiconductor layer ACT may have a monolayer or multilayer structure, and each layer may have a thickness at the atomic level. For example, in an embodiment a two-dimensional semiconductor material may include 1 to 10 layers. For example, the two-dimensional semiconductor material may include 1 to 5 layers. However, embodiments of the present disclosure are not necessarily limited thereto.

In an embodiment, the thickness (e.g., length in the thickness direction of the substrate SUB) of the semiconductor layer ACT may be less than or equal to about 1.5 nm. The semiconductor layer ACT may be provided with a relatively thin thickness, which may increase the flexibility of the transistor.

The semiconductor layer ACT may further include a predetermined dopant to control the mobility of the two-dimensional semiconductor material. In an embodiment, the two-dimensional semiconductor material may be doped with a p-type dopant or an n-type dopant. The p-type dopant or n-type dopant may be doped using ion implantation or chemical doping.

In an embodiment, the semiconductor layer ACT may be formed through a chemical vapor deposition CVD process, a plasma chemical vapor deposition PECVD process, an atomic layer deposition ALD process, or a sputter process.

A gate insulating layer GI may be disposed on (e.g., disposed directly thereon) the semiconductor layer ACT and the substrate SUB. In an embodiment, the gate insulating layer GI may include an inorganic material such as a silicon nitride, a silicon oxide, a silicon nitride, etc.

A gate electrode GE may be disposed on (e.g., disposed directly thereon) the gate insulating layer GI. The gate electrode GE may overlap the semiconductor layer ACT (e.g., in a plan view). Although this specification illustrates an embodiment in which the gate electrode GE is disposed above the semiconductor layer ACT, embodiments of the present disclosure are not necessarily limited thereto, and in some embodiments the gate electrode GE may be disposed below the semiconductor layer ACT.

The gate electrode GE may include a metal, a conductive nitride, or a conductive oxide. In an embodiment, the metal may include, for example, at least one of Au, Ti, W, Mo, Pt, and Ni. The conductive nitride may include, for example, TiN, TaN, WN, etc., and the conductive oxide may include, for example, ITO (Indium Tin Oxide), IZO (Indium Zinc Oxide), etc. However, embodiments of the present disclosure are not necessarily limited thereto.

An interlayer insulating layer ILD may be disposed on (e.g., disposed directly thereon) the gate electrode GE and the gate insulating layer GI. The interlayer dielectric layer ILD may include an organic insulating material or an inorganic insulating material.

A source electrode SE and a drain electrode DE may be disposed on (e.g., disposed directly thereon) the interlayer insulating layer ILD. In an embodiment, each of the source electrode SE and the drain electrode DE may be physically and electrically connected to the semiconductor layer ACT through contact holes formed in the interlayer insulating layer ILD and the gate insulating layer GI.

The above-described semiconductor layer ACT, gate electrode GE, source electrode SE, and drain electrode DE may form one transistor. However, the above-described semiconductor layer is not necessarily limited thereto and may be applied to memory devices such as, for example, DRAM devices. The memory device may have a structure in which the above-described semiconductor layer and a capacitor are electrically connected to each other. Additionally, devices containing the above-described semiconductor layer may be applied to various electronic devices. For example, semiconductor devices may be used for arithmetic operations, program execution, temporary data retention, etc. in electronic devices such as mobile devices, computers, laptops, sensors, network devices, neuromorphic devices, etc. Below is described a manufacturing method of the above-described semiconductor layer according to embodiments of the present disclosure.

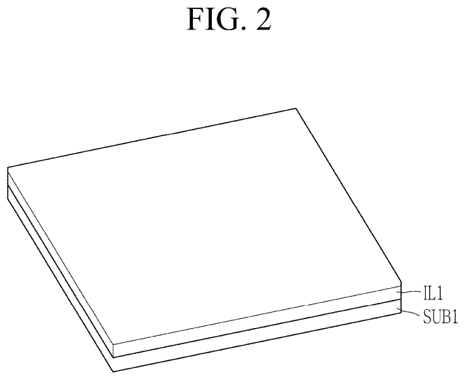

Hereinafter, a method of manufacturing a semiconductor layer for forming the semiconductor layer included in the above-described transistor will be discussed with reference to FIGS. 2 to 10. FIGS. 2 to 10 are diagrams of some components according to a method of manufacturing a semiconductor layer according to some embodiments of the present disclosure.

First, referring to FIG. 2, an insulating layer IL1 disposed on the first substrate SUB1 is prepared. For example, in an embodiment the first substrate SUB1 may comprise silicon Si, and the insulating layer IL1 may include a silicon oxide material. In an embodiment, the thickness of the insulating layer IL1 may be in a range of about 200 nanometers to about 400 nanometers, such as about 300 nanometers. In an embodiment in which the insulating layer IL1 satisfies the above thickness, the insulating layer IL1 may be divided into a hydrophobic region and a hydrophilic region in adjacent regions while maintaining the insulating ability.

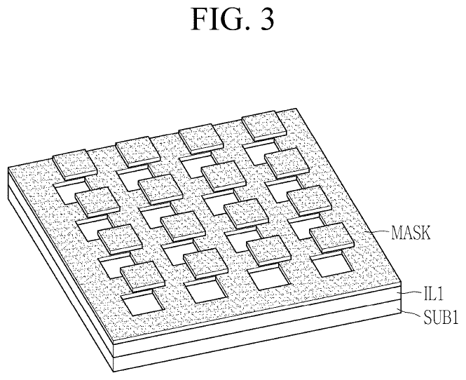

Referring to FIG. 3, in an embodiment a metal layer is then deposited on the insulating layer IL1, and the deposited metal layer is patterned to form a metal mask MASK. A portion of the metal layer corresponding to the location where the semiconductor layer will be deposited later may be removed through a patterning process.

In an embodiment, the thickness of the metal mask MASK may be in a range of about 50 nanometers to about 150 nanometers, such as about 100 nanometers. In an embodiment in which the thickness of the metal mask MASK satisfies the above numerical range, an appropriate surface energy difference may be provided on the insulating layer IL1 in an oxygen plasma process using the metal mask MASK.

The metal mask MASK according to an embodiment may comprise a metal material, and for example, may include at least one of molybdenum (Mo), gold (Au), silver (Ag), copper (Cu), and titanium (Ti). However, embodiments of the present disclosure are not necessarily limited thereto.

The metal mask MASK may be a single metal thin film, a thin film containing two or more metals, or a multi-layer metal thin film containing different metals.

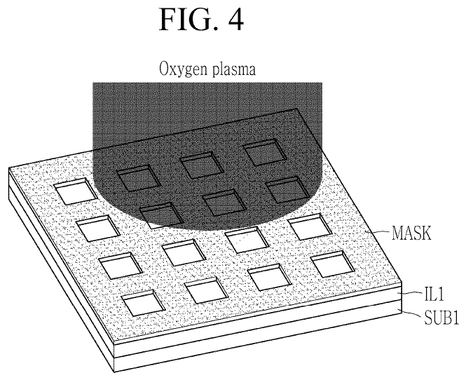

In an embodiment, as shown in FIG. 4, an oxygen plasma process is performed on the metal mask MASK. In an embodiment, the oxygen plasma process may be performed at a power in a range of about 150 W to about 250 W for a time period in a range of about 200 seconds to about 400 seconds. For example, in an embodiment the oxygen plasma process may be performed for about 300 seconds at a power of about 200 W.

When performing an oxygen plasma process, the surface of the insulating layer IL1 exposed by the metal mask MASK may be modified to be hydrophilic. The difference in surface properties between the portion of the insulating layer IL1 covered by the metal mask MASK and the portion of the insulating layer IL1 exposed by the opening of the metal mask MASK may be maximized.

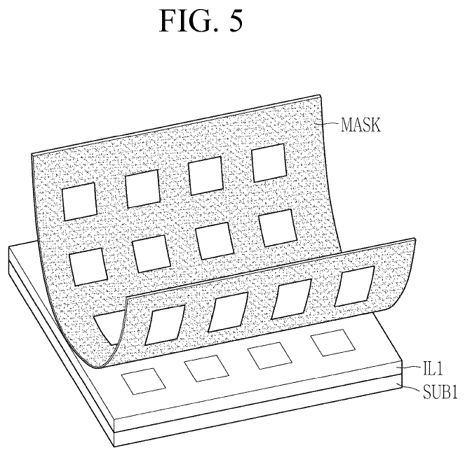

Afterwards, the metal mask MASK is removed as shown in FIG. 5.

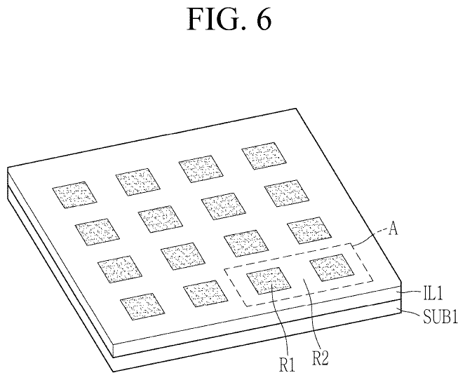

As shown in FIG. 6, the insulating layer IL1 may include a first region R1 and a second region R2 having different surface energies from each other. In an embodiment, the first region R1 may be a hydrophilic region, and the second region R2 may be a hydrophobic region. The first area R1 may correspond to the opening area of the metal mask MASK, and the second area R2 may correspond to an area that was covered by the metal mask MASK during the oxygen plasma process.

The hydrophilic first region R1 may have relatively high surface energy. In contrast, the hydrophobic second region R2 may have relatively low surface energy. The surface energy of the first region R1 may be greater than the surface energy of the second region R2. For example, the first region R1 may have a higher surface energy than the second region R2.

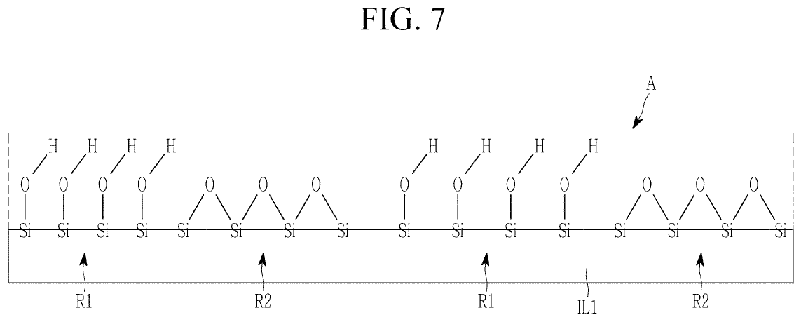

As shown in FIG. 7, in an embodiment the first region R1 is exposed by a metal mask in the oxygen plasma process, whereby the Si—O bonds originally present in the insulating layer IL1 are broken by the oxygen plasma, and new Si—O—H bonds are formed through reaction with adjacent H₂O. Due to this bonding, the first region R1 may include a dangling bond, and the surface energy of the first region R1 may be increased. In contrast, since the second region R2 is covered by a metal mask, the Si—O—Si bond of the insulating layer IL1 may be maintained. The second region R2 maintains a stable bonding state and may have relatively low surface energy.

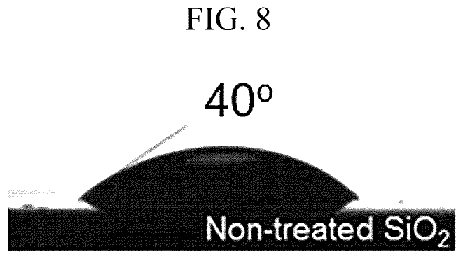

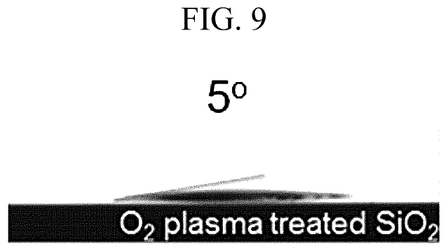

For reference, the second region R2 may exhibit a high contact angle as shown in FIG. 8. The first region R1 may have a low contact angle as shown in FIG. 9. For example, in an embodiment the first region R1 may have a contact angle in a range of about 5 degrees or less, and the second region R2 may have a contact angle in a range of about 30 degrees to about 60 degrees.

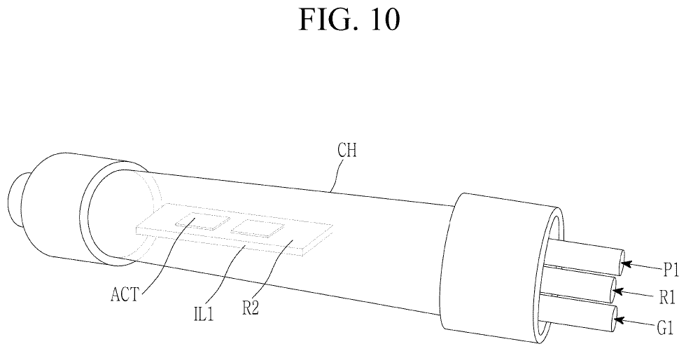

In an embodiment, after forming the insulating layer IL1 that includes the first region R1 and the second region R2 through the aforementioned process, the insulating layer IL1 may be loaded into a chamber CH for forming a semiconductor layer, as illustrated in FIG. 10. This disclosure describes an embodiment in which a method of forming semiconductor layers uses chemical vapor deposition. However, embodiments of the present disclosure are not necessarily limited thereto and the semiconductor layers may be formed using various methods such as plasma enhanced chemical vapor deposition PECVD, atomic layer deposition ALD, or sputtering processes.

In an embodiment, a precursor P1, a reactant R1, and an inert gas G1 may be injected into the chamber CH. Although this specification describes an embodiment in which one precursor is used as an example, embodiments of the present disclosure are not necessarily limited thereto and two or more precursors may be used in some embodiments. The precursor P1 and the reactant R1 may react within the chamber CH to form a semiconductor layer ACT on the first region, such as the region having hydrophilicity.

For example, in an embodiment the precursor P1 may include MoO₃ and may be injected into the chamber CH in an amount in a range of about 0.3 mg to about 0.7 mg. Additionally, the reactant R1 may include S, and may be injected into the chamber CH in an amount in a range of about 330 mg to about 370 mg. In an embodiment, the reactant R1 may be injected in an amount in a range of about 500 to about 1000 times the amount of the precursor P1. For example, the precursor may be injected in an amount of about 0.5 mg, and the reactant may be injected in an amount of about 350 mg. The inert gas G1 according to an embodiment may include at least one of Ar, N₂, and a mixture thereof.

The semiconductor layer ACT according to an embodiment may include a semiconductor material having a layered structure. In an embodiment, a semiconductor material having a layered structure may include a compound represented by the chemical formula Xya in which X is one of Mo, W, Zr, and Re, Y is one of S, Se, and Te, and a may be a natural number greater than or equal to 1. For example, in an embodiment the semiconductor material having the layered structure may include at least one compound selected from MoS₂, MoSe₂, WS₂, WSe₂, MoTe₂, WTe₂, ZrS₂, ZrSe₂, ZrTe₂, ReS₂, ReSe₂, and ReTe₂.

Using the manufacturing method according to an embodiment of the present disclosure, it is easy to provide a pattern of the required form by providing an insulating layer having a hydrophilic region and a hydrophobic region and forming a semiconductor layer directly on the hydrophilic region of the insulating layer. Additionally, the precision and accuracy of the pattern are increased, and the problem of residue remaining may be resolved.

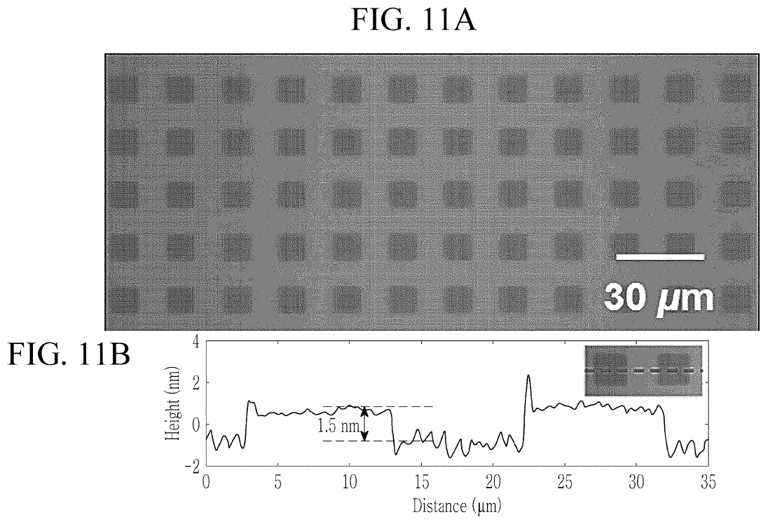

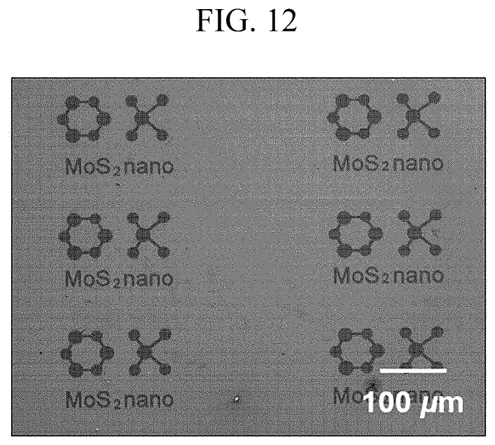

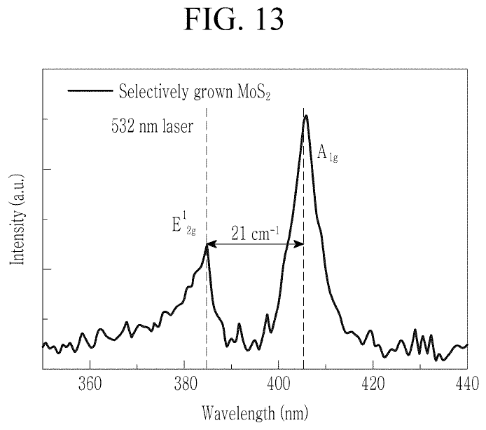

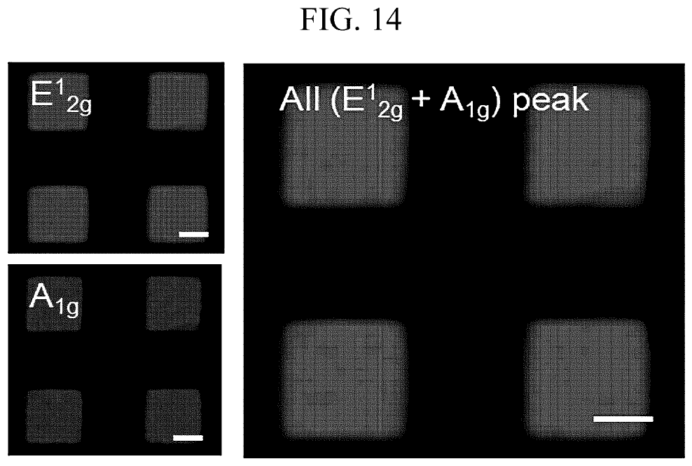

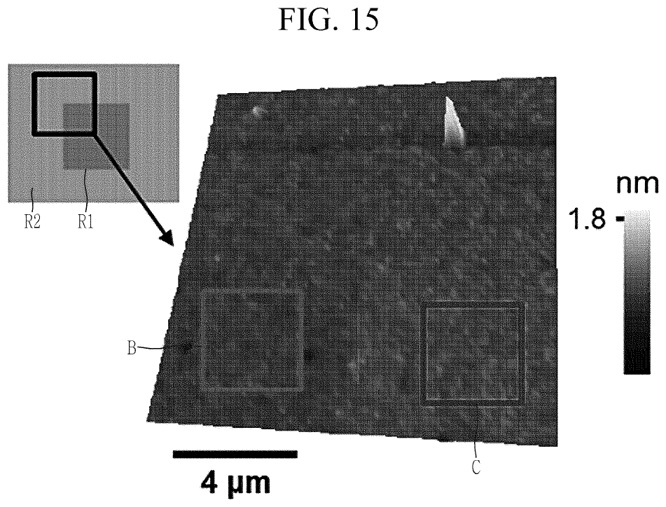

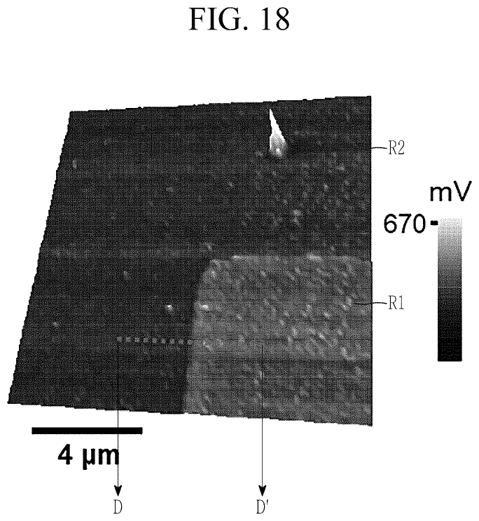

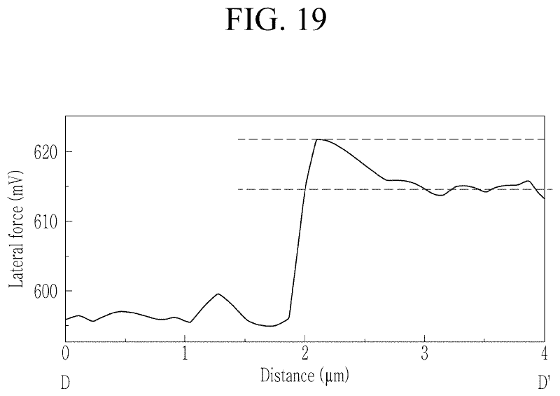

Hereinafter, the characteristics of the semiconductor layer manufactured according to an embodiment will be examined with reference to FIGS. 11 to 19. FIG. 11 (a) is an optical image of a semiconductor layer manufactured according to an example, FIG. 11 (b) is a graph measuring the height of each pattern in FIG. 11 (a), and FIG. 12 is an example. FIG. 13 is a Raman graph of the semiconductor layer manufactured according to an embodiment, FIG. 14 is a Raman mapping image of the semiconductor layer manufactured according to an embodiment, and FIGS. 15 to 17 are atomic force microscopy AFM images of a plasma-treated surface according to an embodiment, FIG. 18 is a Lateral Force Microscopy LFM image of a plasma-treated surface according to an embodiment, and FIG. 19 is a graph showing the lateral force for each area.

FIG. 11 (a) is an optical microscopy image of an insulating layer in which a plurality of semiconductor layers manufactured according to a method of manufacturing a semiconductor layer according to an embodiment of the present disclosure are disposed. Referring to FIG. 11 (a), it may be seen that the semiconductor layer is repeatedly formed only in the first region having hydrophilicity.

FIG. 11 (b) is a height graph for the insulating layer and semiconductor layer of FIG. 11 (a). When the height of the insulating layer was set as a reference point (0 nm), it was confirmed that the semiconductor layer in FIG. 11 (a) was formed stably and repeatedly with an average height of 1.5 nm.

FIG. 12 is a scanning electron microscopy (SEM) image of an example in which a semiconductor layer is manufactured in a specific pattern. As shown in FIG. 12, the semiconductor layer may be manufactured and modified into various shapes according to the user's needs. Thus, it was confirmed that by providing an insulating layer including a hydrophilic region and a hydrophobic region, various types of patterning are possible by stably depositing a semiconductor material thereon.

FIG. 13 is a Raman graph of a semiconductor layer manufactured according to an embodiment, and FIG. 14 is a Raman mapping image of a semiconductor layer manufactured according to an embodiment. Referring to FIGS. 13 and 14, it was confirmed that the semiconductor layers manufactured according to an embodiment of the present disclosure all contained MoS₂ containing Mo and S.

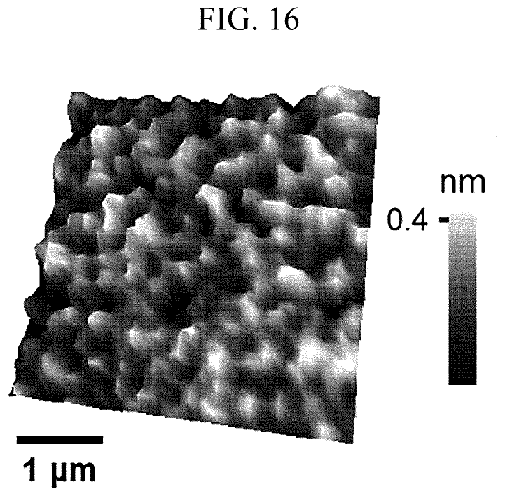

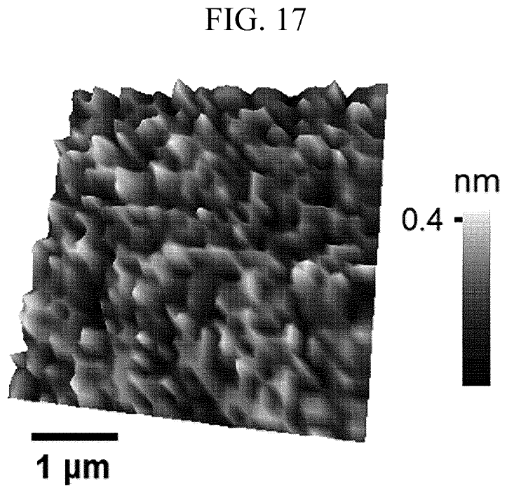

Referring to FIGS. 15 to 17, AFM images of the insulating layer when an oxygen plasma process is performed under the conditions of power of 200 W and process time of 300 s. FIG. 15 is an image representing both the hydrophobic region R2 and the hydrophilic region R1, FIG. 16 is an image representing B, which corresponds to the hydrophobic region in FIG. 15, and FIG. 17 is an image representing C, which corresponds to the hydrophilic region in FIG. 15.

The root mean square RMS value of the surface roughness for the hydrophobic region in FIG. 16 was about 0.13 nm, and the root mean square RMS value of the surface roughness for the hydrophilic region in FIG. 17 was about 0.19 nm.

FIG. 18 is an LFM image of a partial area of the insulating layer manufactured according to an embodiment, and FIG. 19 is a graph showing the lateral force along line D-D′ of FIG. 18. Referring to the graph of FIG. 19, it was confirmed that a lateral force of about 615 mV to 622 mV appeared in the first region showing hydrophilicity. Thus, it was confirmed that the surface energy of the first region was relatively high compared to the surface energy of the second region and had relatively high attraction characteristics. Therefore, when the insulating layer according to an embodiment is loaded into a chamber for depositing a semiconductor material, it may be seen that the semiconductor material is stably formed only in the first region.

Although non-limiting embodiments of the present disclosure have been described in detail above, the scope of embodiments of the present disclosure is not limited thereto, and various modifications made by those skilled in the art are also possible and included in the scope of the present disclosure.

What is claimed is:

1. A method of manufacturing a semiconductor layer, comprising:
preparing an insulating layer comprising a silicon oxide;
forming a metal mask on the insulating layer;
performing an oxygen plasma process on the metal mask;
removing the metal mask; and
loading the insulating layer into a chamber to form a semiconductor layer.

2. The method of manufacturing the semiconductor layer of claim 1, wherein a thickness of the insulating layer is in a range of about 200 nanometers to about 400 nanometers.

3. The method of manufacturing the semiconductor layer of claim 1, wherein the insulating layer includes a first region and a second region having different surface energies from each other through the oxygen plasma process.

4. The method of manufacturing the semiconductor layer of claim 3, wherein the first region has a higher surface energy than the second region.

5. The method of manufacturing the semiconductor layer of claim 3, wherein the first region has hydrophilicity and the second region has hydrophobicity.

6. The method of manufacturing the semiconductor layer of claim 3, wherein:
the first region include a Si—O—H bond; and
the second region includes a Si—O—Si bond.

7. The method of manufacturing the semiconductor layer of claim 1, wherein the metal mask comprises at least one compound selected from molybdenum (Mo), gold (Au), silver (Ag), copper (Cu), and titanium (Ti).

8. The method of manufacturing the semiconductor layer of claim 1, wherein the metal mask has a thickness in a range of about 50 nanometers to about 150 nanometers.

9. The method of manufacturing the semiconductor layer of claim 1, wherein the metal mask is formed through a patterning process after forming a metal layer on the insulating layer.

10. The method of manufacturing the semiconductor layer of claim 1, wherein the oxygen plasma process is performed at a power in a range of about 150 W to about 250 W.

11. The method of manufacturing the semiconductor layer of claim 1, wherein the oxygen plasma process is performed for a time period in a range of about 200 seconds to about 400 seconds.

12. The method of manufacturing the semiconductor layer of claim 3, further comprising injecting a precursor, a reactant, and an inert gas into the chamber to form the semiconductor layer.

13. The method of manufacturing the semiconductor layer of claim 12, wherein:
the precursor is injected in an amount in a range of about 0.3 mg to about 0.7 mg; and
the reactant is injected in an amount in a range of about 330 mg to about 370 mg.

14. The method of manufacturing the semiconductor layer of claim 12, wherein the reactant is injected in an amount in a range of about 500 to about 1000 times that of the precursor.

15. The method of manufacturing the semiconductor layer of claim 12, wherein the precursor and the reactant react to form a semiconductor layer having a layered structure on the first region.

16. The method of manufacturing the semiconductor layer of claim 15, wherein:
the semiconductor layer having the layered structure includes a compound represented by a chemical formula XYa,
wherein X is one of Mo, W, Zr, and Re, Y is one of S, Se, and Te, and a is a natural number greater than or equal to 1.

17. The method of manufacturing the semiconductor layer of claim 16, wherein the semiconductor layer having the layered structure includes at least one compound selected from MoS₂, MoSe₂, WS₂, WSe₂, MoTe₂, WTe₂, ZrS₂, ZrSe₂, ZrTe₂, ReS₂, ReSe₂, and ReTe₂.

18. A transistor, comprising:
a substrate;
a semiconductor layer disposed on the substrate;
a gate electrode overlapping a portion of the semiconductor layer; and
a source electrode and a drain electrode electrically connected to the semiconductor layer,
wherein the semiconductor layer is manufactured through the method of manufacturing the semiconductor layer of claim 1.

19. The transistor of claim 18, wherein
the semiconductor layer includes a compound represented by a chemical formula XYa,
wherein X is one of Mo, W, Zr, and Re, Y is one of S, Se, and Te, and a is a natural number greater than or equal to 1.

20. The transistor of claim 19, wherein the semiconductor layer includes at least one compound selected from MoS₂, MoSe₂, WS₂, WSe₂, MoTe₂, WTe₂, ZrS₂, ZrSe₂, ZrTe₂, ReS₂, ReSe₂, and ReTe₂.

21. A method of manufacturing a semiconductor layer, comprising:
preparing a substrate comprising silicon;
forming an insulating layer comprising silicon oxide on the substrate;
forming a metal layer on the insulating layer;
patterning the metal layer to form a metal mask having an opening area;
performing an oxygen plasma process on the metal mask, the oxygen plasma process forming a first region of the insulating layer that is exposed by the opening area of the metal mask during the performing of the oxygen plasma process and a second region of the insulating layer that is covered by the metal mask during the performing of the oxygen plasma process; and
forming the semiconductor layer on the first region,
wherein the first region has hydrophilicity and the second region has hydrophobicity.

22. The method of claim 21, wherein the first region has a higher surface energy than the second region.

23. The method of claim 21, wherein the semiconductor layer is formed on the first region through a chemical vapor deposition process, a plasma chemical vapor deposition process, an atomic layer deposition process or a sputter process.

24. The method of claim 21, wherein:
the first region has a contact angle in a range of about 5 degrees or less; and
the second region has a contact angle in a range of about 30 degrees to about 60 degrees.
